(19) United States
(12) Patent Application Publication
(10) Pub. No.: US 2026/0164695 A1
(43) Pub. Date: Jun. 11, 2026

(54) SEMICONDUCTOR HETEROSTRUCTURE DEVICES WITH GRADED BARRIER LAYERS

(71) Applicant: NXP USA, Inc., AUSTIN, TX (US)

(72) Inventors: Bernhard Grote, Phoenix, AZ (US); Jianwei Wan, Chandler, AZ (US); Congyong Zhu, Gilbert, AZ (US); Bruce McRae Green, Gilbert, AZ (US); Hernan Rueda, Chandler, AZ (US)

(21) Appl. No.: 18/977,770

(22) Filed: Dec. 11, 2024

(51) Int. Cl. H10D 30/47; H10D 62/85

(52) U.S. Cl. CPC H10D 30/475; H10D 62/8503

(57) ABSTRACT

Improved transistor performance for RF switching and amplification can be achieved by using a back barrier layer beneath the channel layer in a semiconductor heterostructure based transistor such as a gallium-nitride based high electron mobility transistor. The back barrier layer is formed from a solid solution of semiconductor materials with a composition that varies with distance from the channel layer. The back barrier layer beneath the channel layer can improve performance of the transistor by improving confinement of the two-dimensional carrier gas formed in the channel layer at the interface between the channel layer and a conventional barrier layer above the channel. The variable, or “graded”, composition of the thin (e.g., less than 50 nm) back barrier can mitigate or eliminate formation of parasitic carriers observed in conventional back barriers which can introduce performance trade-offs.

### TECHNICAL FIELD

Embodiments of the subject matter described herein relate to semiconductor heterostructure-based semiconductor devices.

### BACKGROUND

Semiconductor heterostructures can be used to form heterostructure field effect transistors (HFETs) in which a two-dimensional charge gas (2DCG) such as a two-dimensional electron gas (2DEG) or a two-dimensional hole gas (2DHG) is formed at or near the interface between semiconductor layers with different bandgap energies. In such transistors, formation of the 2DCG can be controlled using a gate electrode which can be appropriately biased to allow or suppress formation of the 2DCG between a drain terminal and a source terminal of the transistor.

### SUMMARY

In an example embodiment, a transistor includes a substrate; a semiconductor buffer layer formed on the substrate; and a semiconductor heterostructure formed above the buffer layer. The heterostructure includes a back barrier layer formed pseudomorphically directly on the buffer layer; an upper barrier layer disposed above the back barrier layer; and a channel layer formed between the back barrier layer and the upper barrier layer that contacts the back barrier layer at a first interface and contacts the upper barrier layer at a second interface.

The transistor includes a first current terminal electrically coupled to a first end of the channel layer; a second current terminal electrically coupled to a second end of the channel layer; and a gate electrode electrically coupled to the channel layer and disposed above the channel layer between the first current terminal and the second current terminal.

The channel layer is formed from a first semiconductor material; and the back barrier layer is formed from a solid solution of the first semiconductor material and a second semiconductor material. The solid solution has a composition that varies with distance from the first interface in a direction perpendicular to the first interface. The upper barrier layer is formed by a third semiconductor material. The channel layer and the upper barrier layer are jointly configured and arranged to cause formation of a two-dimensional charge gas (2DCG) in the channel layer at the second interface.

In another example embodiment, a transistor includes a substrate; a semiconductor buffer layer formed on the substate from a first semiconductor material; and a semiconductor heterostructure formed above the buffer layer. The heterostructure includes a back barrier layer disposed directly on the buffer layer; an upper barrier layer disposed above the back barrier layer; and a channel layer formed between the back barrier layer and the upper barrier layer that contacts the back barrier layer at a first interface and contacts the upper barrier layer at a second interface.

The transistor also includes a first current terminal electrically coupled to a first end of the channel layer; a second current terminal electrically coupled to a second end of the channel layer; and a gate electrode electrically coupled to the channel layer and disposed above the channel layer between the first current terminal and the second current terminal.

The channel layer is formed from the first semiconductor material; and the back barrier layer is formed from a solid solution of the first semiconductor material and a second semiconductor material. The solid solution has a composition that varies with distance from the first interface in a direction perpendicular to the first interface. The upper barrier layer is formed by a third semiconductor material. The channel layer and the upper barrier layer are jointly configured and arranged to cause formation of a two-dimensional charge gas (2DCG) in the channel layer at the second interface.

### BRIEF DESCRIPTION OF THE DRAWINGS

The present disclosure is illustrated by way of examples, embodiments and the like and is not limited by the accompanying figures, in which like reference numbers indicate similar elements. Elements in the figures are illustrated for simplicity and clarity and have not necessarily been drawn to scale. The figures along with the detailed description are incorporated and form part of the specification and serve to further illustrate examples, embodiments and the like, and explain various principles and advantages, in accordance with the present disclosure, wherein:

FIG. 1 is a schematic cross-sectional view of an example transistor according to one or more embodiments;

FIG. 2 shows atomic composition profiles of two example barrier layers suitable for use in the transistor of FIG. 1

FIG. 3 is a plot of the conduction band edge and carrier concentrations for a device with a graded back barrier layer with a graded composition of InGaN compared with the conduction band edge and carrier concentration in a conventional device with a uniform back barrier layer.

FIG. 4 is a plot showing current-voltage characteristics of the devices compared in FIG. 3.

FIG. 5 is a plot of the conduction band edge and carrier concentrations for a device with a graded back barrier layer with a graded composition of AlGaN compared with the conduction band edge and carrier concentration in a conventional device with a uniform back barrier layer.

FIG. 6 is a plot showing current-voltage characteristics of the devices compared in FIG. 5.

### DETAILED DESCRIPTION

The following detailed description provides examples for the purposes of understanding and is not intended to limit the invention or the application and uses of the same. Furthermore, there is no intention to be bound by any expressed or implied theory presented in the preceding technical field, background, or the following detailed description.

For simplicity and clarity of illustration, elements in the Drawings are not necessarily drawn to scale. For example, the dimensions of some of the elements or regions in the figures may be exaggerated relative to other elements or regions to help improve understanding of embodiments of the invention. Directional references such as “top,” “bottom,” “left,” “right,” “above,” “below,” and so forth, unless otherwise stated, are not intended to require any preferred orientation, and are made with reference to the orientation of the corresponding figure or figures for purposes of illustration. In addition, the Figures and Detailed Description may omit well-known and conventional features for clarity.

It will be appreciated that although current terminals of transistors described herein may be referred to by conventional names associated with field effect transistors and the like such as “source” and “drain,” embodiments herein can employ any suitable transistor technologies, including those in which the terms “source” and “drain” are not used. It will be further understood that source and drain terminals may be interchangeable, depending on how a transistor is connected within a larger circuit.

Although semiconductor heterostructure devices such as HFETs can be attractive for high voltage (e.g., switching of DC voltages>20V) and high-frequency applications, conventional heterostructure devices can have performance trade-offs that arise from complicated device physics of such structures. As one example, although GaN heterostructures enable formation of a 2DEG channel with switchable conductivity which is attractive for use in transistors, these HEMTs can also have undesirable leakage currents in the off state.

Some HFETs including GaN HEMTs include an additional barrier layer beneath the channel layer in which the 2DCG is formed (a “back barrier”). The back barrier has a different electronic bandgap energy from the channel layer to improve confinement of the 2DCG. This improved confinement can improve pinch-off characteristics and leakage current performance but can also introduce unwanted side effects. For example, polarization charges formed at interface between the channel layer and the back barrier can induce formation of a parasitic 2DCG that can interfere with and degrade the device pinch-off characteristics. Moreover, charge carrier accumulation resulting in a parasitic 2DCG may also occur intermittently at steps in the band edge as bias is applied to turn off the device. Accordingly, devices and methods according to embodiments herein employ heterostructures with back barrier layers engineered to simultaneously improve confinement of the 2DCG in the channel layer while also mitigating or eliminating undesired effects arising from formation of parasitic 2DCGs at or close to the back barrier.

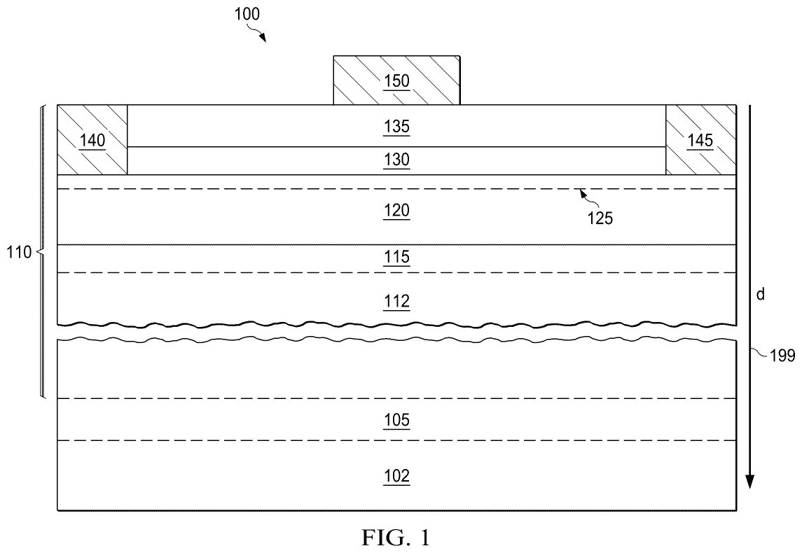

FIG. 1 is a simplified cross-sectional schematic of an example transistor according to one or more embodiments. Although the example transistor 100 is depicted as a high electron mobility transistor (HEMT), it will be appreciated that embodiments disclosed herein include high hole mobility transistors (HHMTs) as well as HEMTs. It will also be appreciated that although the transistor 100 is depicted with a metal-semiconductor interface at the gate (where a Schottky contact is formed), that a metal-insulator-semiconductor interface could also be employed. A suitably doped semiconductor material can also be employed as a gate electrode. It will be further understood that although embodiments disclosed herein may be described with reference to transistors for purposes of illustration, such embodiments are not limited to transistors and can include any other suitable semiconductor devices, including optoelectronic devices such as lasers, light-emitting diodes, photo-detectors and solar-cells, as nonlimiting examples.

The transistor 100 is formed on a substrate 102, which can be any suitable substrate including, but not limited to, silicon, silicon carbide (SiC), silicon-on-insulator (SOI), or diamond. A semiconductor heterostructure (the heterostructure 110) is formed on the substrate 102. In the example of FIG. 1, the heterostructure 110 is formed on a nucleation layer 105 which facilitates formation of the heterostructure 110 on the substrate 102. As shown in FIG. 1, the heterostructure also includes a buffer layer 112 that can serve to reduce strain and propagation of lattice defects into other layers of the heterostructure 110 (e.g., strain relaxation extending into other layers such as a back barrier layer described further below). It will be appreciated, however, that in one or more embodiments, layers such as the nucleation layer 105 or the buffer layer 112 are absent and in one or more embodiments, additional layers may be present which are not shown. In one or more embodiments, a transistor such as the transistor 100 is a gallium-nitride-based (GaN-based) HEMT. The heterostructure 110 is described in further detail below in connection with such a GaN-based HEMT.

In the simplified example of FIG. 1, the heterostructure 110 includes a GaN channel layer 120 which is disposed between two barrier layers: an upper barrier layer 130 that is a solid solution of aluminum nitride (AlN) and GaN, and a graded-composition barrier layer 115 (a “back barrier”), which are described further below. In the example of FIG. 1, the cap layer 135 is a layer of GaN disposed above the upper barrier layer 130. The channel layer 120 and the upper barrier layer 130 are configured such that a 2DEG 125 is formed in the channel layer 120 at or near an interface between the channel layer 120 and the upper barrier layer 130. That is, the electronic band structure of the channel layer 120 and the upper barrier layer 130 result in formation of a region at the interface between the channel layer 120 and the upper barrier layer 130 where the conduction band edge of the channel layer 120 is lower than the Fermi energy, resulting in formation of a 2DEG in that region.

A back barrier such as the graded-composition barrier layer 115 is an additional barrier layer which can improve confinement of the 2DEG 125 when compared with conventional heterostructure-based HEMTs which lack a back barrier beneath the layer in which the 2DEG forms (e.g., the channel layer 120). Improved confinement can enable performance enhancement via gate length scaling by addressing undesired short channel effects such as poor pinch-off, high sub-threshold leakage, drain induced barrier lowering (“DIBL”, which causes the threshold voltage, V_{T}, of a transistor to depend on the drain to source voltage, V_{DS}), and reduced output resistance.

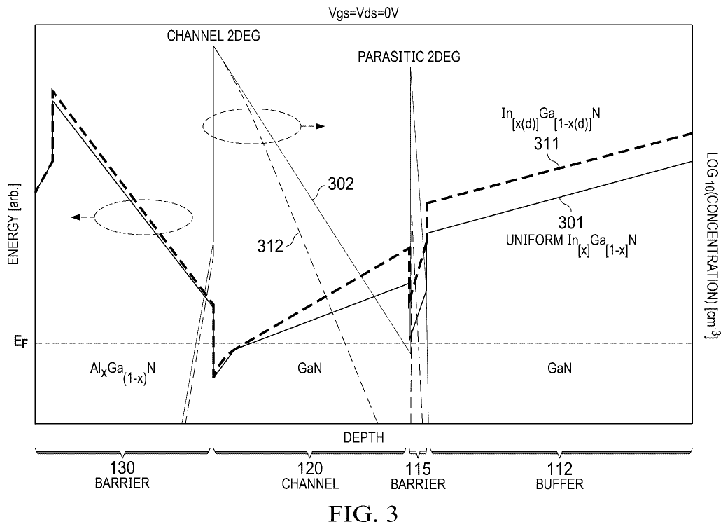

Back barriers with uniform elemental composition have been employed in GaN HEMTs for the purposes above but can have disadvantages (discussed above and in further detail below in connection with FIGS. 3-6). For example, when combined with a GaN channel layer, a uniform pseudomorphically grown layer of InₓGa₁₋ₓN on a suitable buffer layer can be used as a back barrier to improve 2DEG confinement by lifting the conduction band edge in the buffer layer due to polarization induced electric fields and conduction band discontinuities. However, such uniform composition back barriers can result in formation of an additional parasitic 2DEG in the back barrier or intermittent parasitic 2DEG accumulation as bias is applied. This parasitic 2DEG may partially negate some of the benefits of the back barrier and may result in unwanted effects such as introducing undesirable transconductance variations. It will be understood that similar effects can occur in related material systems in which the electronic charge carriers are holes rather than electrons.

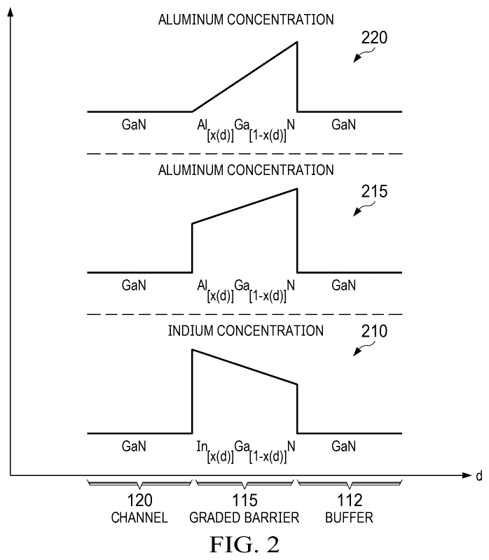

FIG. 2 shows three elemental composition profiles for a graded barrier layer such as the barrier layer 115 of FIG. 1 according to embodiments disclosed herein. In all three example profiles 210, 215, 220, the channel layer 120 and buffer layer 112 are GaN.

In the profile 210, the graded barrier layer 115 is a solid solution of indium nitride (InN) and GaN having a composition that can be expressed as In_{[x(d)]}Ga_{[1-x(d)]}N, where d indicates depth within the heterostructure 110 (as indicated by the arrow 199 of FIG. 1) and x(d) is the atomic fraction of indium, where a value of 1.0 corresponds to pure InN and a value of zero corresponds to pure GaN. In the profile 210, the indium content is zero in the channel layer 120, corresponding to GaN. The indium content of the graded barrier layer 120 has a maximum value closest to the channel layer 120 and decreases toward the buffer layer 112. The graded composition profile induces a bulk charge polarization that enhances the electric displacement field perpendicular to the back-barrier layer which can further lift the conduction band, enhance carrier confinement, and reduce parasitic charge accumulation. The corresponding induced polarization charge would have the same polarity as the charge carriers in the 2DCG.

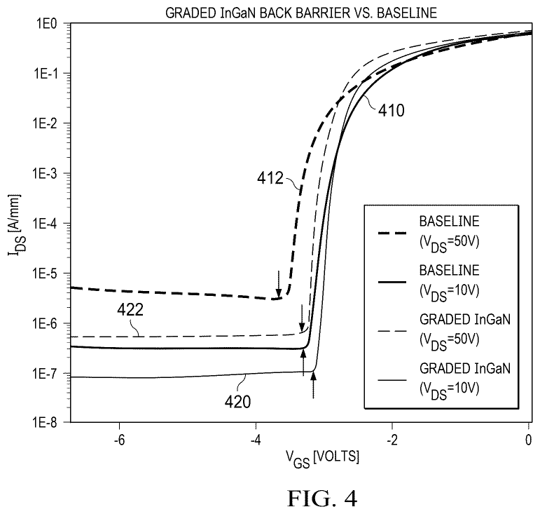

FIG. 3, described further below, includes a plot that shows the resulting conduction band energy relative to the Fermi level energy for a representative heterostructure that includes a graded barrier layer with a composition according to the profile 210. Specific advantages of a graded-composition back barrier with a composition profile such as the profile 210 are discussed further below in connection with FIGS. 3-4.

In the profile 215 the graded barrier layer 115 is a solid solution of aluminum nitride (AlN) and GaN having a composition that can be expressed as Al_{[x(d)]}Ga_{[1-x(d)]}N, where x(d) corresponds to the atomic percentage of Al relative to the percentage of Ga. In the profile 220, the Al content is zero in the channel layer 120, corresponding to GaN. The proportion of AlN in the graded barrier layer 115 has a minimum value closest to the channel layer 120 and increases with increasing depth toward the buffer layer 112.

In the profile 220, the graded barrier layer 115 is a solid solution of aluminum nitride (AlN) and GaN having a composition that can also be expressed as Al_{[x(d)]}Ga[_{1-x(d)]}N, where x(d) corresponds to the atomic percentage of Al relative to the percentage of Ga. However, In the profile 220, the profile is triangular or approximately triangular. The AlN content is zero in the channel layer 120, corresponding to GaN. The proportion of AlN in the graded barrier layer 115 has a minimum value closest to the channel layer 120 and increases with increasing depth toward the buffer layer 112 It will be appreciated that, in one or more embodiments, triangular or approximately triangular profile may have an Al concentration that is greater than zero at one or both ends.

In one or more embodiments, a back barrier layer such as a graded composition back barrier layer 115 is formed pseudomorphically on a buffer layer such as the buffer layer 112 that has a different elemental composition from the back barrier layer. For example, in one or more embodiments, a graded composition back barrier layer with a variable composition of the form Al₍ₓ₎Ga₍₁₋ₓ₎N or In₍ₓ₎Ga₍₁₋ₓ₎N is formed pseudomorphically on a uniform composition GaN buffer layer. In other words, in one or more such embodiments, the back barrier layer is pseudormorphic with—and thus conforms to—the lattice structure of the buffer layer on which it is formed and is under strain. Such a pseudomorphically formed back barrier layer does not exhibit strain relaxation that results in the lattice structure of the back barrier layer “relaxing” toward the expected bulk lattice structure of the back barrier layer. In one or much such embodiments, the thickness of the back barrier layer is chosen such that the back barrier layer is thinner than a critical relaxation thickness above which strain relaxation of the back barrier layer is observed or otherwise expected to occur. One skilled in the art will appreciate that the critical relaxation thickness for a given back barrier layer will depend (at least) on the composition of the back barrier layer and the composition and structure of the underlying buffer layer. For instance, in one or more embodiments, a back barrier layer has a thickness of less than 50 nanometers.

It will be understood that descriptions of a barrier profile as trapezoidal, triangular, linear, and so forth will be subject to limitations in the fabrication processes chosen to form the back barrier as well as subsequent processing of the substrate. For instance, it will be understood that diffusion may occur during barrier formation or subsequent to barrier formation. Along these lines, a composition profile described as having a step change or other abrupt change in composition may instead have a very large composition gradient. As an example, the indium concentration gradient in the profile 210 may be a least ten times steeper at the edges of the graded barrier 115 compared to the indium concentration gradient within the rest of the graded barrier 115. Similarly, the aluminum concertation gradient of the profile 215 at the edges of the graded barrier 115 may be at least ten times steeper than the aluminum concentration gradient within the rest of the graded barrier 115. Along the same lines, the concentration gradient in the composition profile 220 at the interface between the graded barrier 115 and the buffer 112 may be at least ten times steeper than the aluminum concentration gradient within the rest of the graded barrier 115.

FIG. 3 is a plot that includes a curve 311 of the conduction band edge energy in thermal equilibrium for a heterostructure with a GaN channel layer and a back barrier that is a solid solution of GaN and InN (i.e., InGaN) with a composition profile such as the profile 210 of FIG. 2 as a function of depth in the heterostructure 110 of FIG. 1. The resulting (electron) carrier concentration is shown by the curve 311. Because the nominal bandgap energy of InN (˜0.7 eV) is significantly smaller than the nominal bandgap energy of ˜3.4 eV for GaN, a solid solution of InN and GaN will have an intermediate bandgap energy that is less than the bandgap energy for pure GaN.

As a result, the conduction band edge forms a well in the back-barrier layer 115 which results in the accumulation of electrons in an undesired parasitic 2DEG within the barrier layer 115. However, when compared with the conduction band edge of similar heterostructure with a conventional InGaN back-barrier with a fixed composition (see the curve 301) and electronic carrier concentration for the conventional back barrier (see the curve 302), it is apparent that a graded-composition InGaN back barrier results in better confinement of the 2DEG formed in the channel layer 120 and also results in a significantly lower carrier concentration in the parasitic 2DEG formed in the barrier layer 115 when compared to a conventional InGaN back barrier with a fixed proportion of InN. For this comparison, the aluminum concentration in the barrier 130 of the structure corresponding to conduction band edge 311 has been increased slightly with respect to the conventional back-barrier structure 301 to yield the same 2DCG sheet charge as for the conventional back-barrier structure in the presence of the increased confinement from the back-barrier.

FIG. 4 shows four transfer functions relating drain current I_{DS} to applied gate voltage (V_{GS}) for two heterostructure transistors at two values of V_{DS}. The curve 410 corresponds to a GaN HEMT with a conventional back-barrier with constant composition profile at V_{DS}=10V and the curve 412 corresponds to the same device at V_{DS}=50V. The curves 420 and 422 correspond to an otherwise similar transistor that includes a graded-composition InGaN barrier according to one or more embodiments, with the conduction band diagram shown in FIG. 3, at V_{DS}=10V and V_{DS}=50V, respectively.

It will be appreciated that the transistor with the graded-composition InGaN barrier exhibits an improved pinch-off with higher threshold voltage with improved sub-threshold slope as well as increased transconductance around a typical RF bias point for class AB amplifiers and with a smaller leakage current value than the GaN HEMT using a conventional back barrier for the same value of V_{DS} (i.e., the transistor with the graded-composition barrier according to embodiments herein turns off more completely when a negative voltage is applied to the gate). It will also be appreciated that the DIBL effect on threshold voltage, i.e. the shift in threshold voltage between V_{DS}=10V and V_{DS}=50V is smaller for the transistor with the graded-composition back barrier leading to more desirable properties such as increased output resistance.

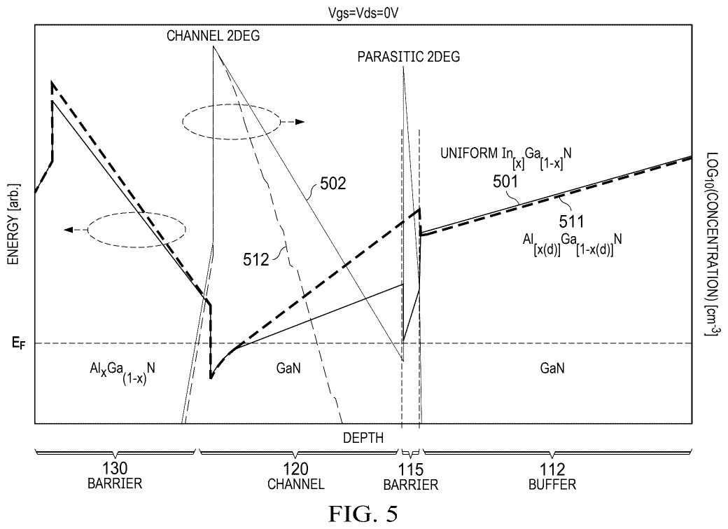

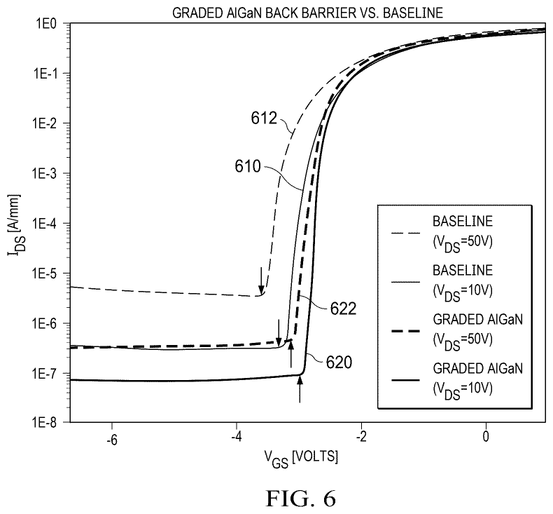

FIG. 5 is a plot that shows the thermal equilibrium conduction band energy relative to the Fermi level energy for a representative heterostructure that includes an AlGaN graded-composition barrier layer with a composition according to the profile 220. In the example of FIG. 5 and FIG. 6, the graded barrier layer 115 has a composition of pure GaN at the interface with the channel layer 120 with an increasing concentration of aluminum toward the buffer layer 112, reaching a composition of Al_{(0.10)}Ga_{(0.90)}N nearer the interface with the buffer layer 112 before decreasing again.

Because aluminum nitride has a bandgap energy of ˜6 eV a solid solution of GaN and AlN will have a higher bandgap energy than pure GaN. As a result, the conduction band edge for the graded AlGaN back barrier (see curve 511) does not form a well in which charge carriers can accumulate which can occur with InGaN back barriers having uniform (or approximately uniform) composition (see the curve 501 as well as the curves 301, 311 of FIG. 3). However, parasitic charge carrier accumulation may still occur intermittently at steps in the band edge as bias is applied to turn off the device. As shown in the curve 512, the 2DEG is better confined by a graded AlGaN back barrier than by a constant composition InGaN back barrier (compare the curve 502) and the electronic carrier concentration plot of curve 512 exhibits no formation of a parasitic 2DEG in the graded barrier barrier layer 115.

Since AlGaN, when grown pseudomorphically on GaN, tends to experience tensile strain, it is desirable to use a composition gradient that has a slope opposite to a compressively strained InGaN layer to produce a polarization bulk charge favourable for enhancing the confinement given that the polarization coefficients in AlN, InN, and GaN all have the same sign. Consequently, a composition profile such as the profile 215 or the profile 220 can result in improved confinement of the 2DCG formed in the channel layer compared to AlGaN back-barriers with constant composition as well.

FIG. 6 shows four transfer functions relating drain current to applied gate voltage (V_{GS}) for two heterostructure transistors at two values of V_{DS}. The curve 610 is the curve for the GaN HEMT with a conventional back-barrier with constant composition profile at V_{DS}=10V and the curve 612 is the curve for the same device at V_{DS}=50V. The curves 620 and 622 correspond to a transistor that includes a graded-composition AlGaN barrier with the conduction band diagram shown in FIG. 5, at V_{DS}=10V and V_{DS}=50V, respectively It will be appreciated that the transistor with the graded-composition AlGaN barrier exhibits an improved pinch-off with higher threshold voltage, with improved sub-threshold slope as well as increased transconductance around a typical RF bias point for class AB amplifiers. The HEMT with the graded AlGaN barrier also exhibits a smaller leakage current value than the GaN HEMT using a conventional InGaN back barrier for the same value of V_{DS} (i.e., the transistor with the graded-composition AlGaN barrier according to embodiments herein turns off more completely when a negative voltage is applied to the gate). It will also be appreciated that the DIBL effect on threshold voltage between V_{DS}=10V and V_{DS}=50V is smaller for the transistor with the graded-composition AlGaN back barrier leading to more desirable properties such as increased output resistance.

It will be understood that although embodiments herein may be described with reference to particular transistor types (e.g., n-type HEMTs operated as depletion-mode devices in which the channel layer is electrically conductive unless a suitable bias is applied to deplete the channel), that nothing herein is intended to limit embodiments to any specific circuit topology or transistor type. For instance, graded back barriers related to examples discussed herein may be employed in heterostructure devices, including, but not limited to HHMTs or enhancement mode devices of either polarity. Furthermore, it will be understood that other materials may be used than those specified including, but not limited to, back barriers formed from other solid solutions such as AlGaN, AlGaInN and AlScGaN.

In one or more embodiments, a buffer layer of GaN is disposed between the back barrier layer and the substrate. In one or more such embodiments, the back barrier layer is formed directly on the buffer layer. In this context, a GaN buffer layer refers to a layer consisting essentially of GaN to the exclusion of any other material in sufficient quantity to alter the crystal structure, lattice constant, or other measurable physical characteristics of GaN in such a way as to change the function of a claimed device or the mechanism by which a claimed result is achieved.

### VARIOUS EXAMPLES

Features of embodiments may be understood by way of one or more of the following examples:

Example 1: A semiconductor device or method of fabricating a semiconductor device that includes a substrate, a buffer layer formed on the substrate, and a semiconductor heterostructure formed above the buffer layer. The heterostructure includes a back barrier layer disposed directly on the buffer layer substrate, an upper barrier layer disposed above the back barrier layer, and a channel layer formed between the back barrier layer and the upper barrier layer that contacts the back barrier layer at a first interface and contacts the upper barrier layer at a second interface. The channel layer is formed by a first semiconductor material and the back barrier layer is formed from a solid solution of the first semiconductor material and a second semiconductor material. The solid solution has a composition that varies with distance from the first interface in a direction perpendicular to the first interface. The upper barrier layer is formed by a third semiconductor material and the channel layer and the upper barrier layer are jointly configured to cause formation of a two-dimensional charge gas (2DCG) in the channel layer at the first interface. The device or method also includes a first current terminal electrically coupled to a first end of the channel layer; a second current terminal electrically coupled to a second end of the channel layer; and a gate electrode disposed above the back barrier layer between the first current terminal and the second current terminal.

Example 2: The device or method of Example 1, where the channel layer is formed from gallium nitride (GaN), and the back barrier layer is a solid solution of GaN with indium nitride (InN) having a concentration of indium that is highest near the first interface and decreases away from the first interface and toward the substrate.

Example 3: The device or method of Example 1 or Example 2, where the back barrier layer has a first composition near the first interface that is at least 15% InN and a remainder of the first composition is GaN. The back barrier layer has and a second composition away from the first interface that is less than 10% InN and a remainder of the second composition is GaN.

Example 4: The device or method of any one of Examples 1-3, where a proportion of InN in the barrier layer decreases linearly with distance from the first interface along the direction perpendicular to the first interface in at least a portion of the back barrier layer.

Example 5: The device or method of any one of Examples 1-4, where an electronic carrier concentration of the 2DCG at the second interface is at least 100 times larger than an electronic carrier concentration of a parasitic 2DCG formed in the back barrier layer at the first interface.

Example 6: The device or method of Example 1, where the channel layer is formed from gallium nitride (GaN), and the back barrier layer is a solid solution of GaN with aluminum nitride (AlN) having a concentration of aluminum that is lowest at the first interface and increases away from the first interface.

Example 7: The device or method of 6, where the back barrier layer has a first composition at the first interface that is less than 1% AlN.

Example 8: The device or method of Example 6 or Example 7, where the back barrier layer has a second composition away from the first interface that is at least 10% AlN.

Example 9: The device or method of any one of Examples 6-8, where the proportion of AlN of the back barrier layer increases with distance from the first interface along the direction perpendicular to the first interface in at least part of the back barrier layer.

Example 10: The device or method of any one of Examples 6-9, where a proportion of AlN of the back barrier layer increases linearly with distance from the first interface along the direction perpendicular to the first interface in art least part of the back barrier layer.

Example 11: The device or method of any one of Examples 6-10, where a proportion of AlN of the back barrier layer increases with distance from the first interface along the direction perpendicular to the first interface before decreasing with distance once the distance from the interface is greater than a predetermined distance.

Example 12: The device or method of any one of Examples 1-11, where the back barrier layer and the channel layer are jointly configured and arranged to prevent formation of a parasitic 2DCG in the back barrier layer.

Example 13: The device or method of any one of Examples 1-12, where an electronic carrier concentration of a 2DCG at the second interface is at least 100 times larger than an electronic carrier concentration of a parasitic 2DCG formed in the back barrier layer at the first interface.

Example 14: The device or method of any one of Examples 1-13, where the back barrier layer and the channel layer are jointly configured to prevent formation of a parasitic 2DCG in the back barrier layer in the back barrier layer at the first interface.

Example 15: The device or method of any one of Examples 1-14 where a composition gradient within the back-barrier is configured to produce polarization within the back barrier layer that opposes accumulation of charge carriers having a polarity that is the same as a polarity of charge carriers in the 2DCG formed in the channel layer.

Example 16: The device or method of any one of Examples 1-15, where the semiconductor device is transistor.

Example 17: The device or method of any of Examples 1-16 in which the back barrier layer is pseudomorphically formed directly on a buffer layer disposed between the back barrier layer and the substrate.

Example 18 The device of method of any of Examples 1-17 that includes a GaN buffer layer beneath the back barrier layer.

Example 19: The device of method of any of Examples 1-18 in which the back barrier layer is thinner than a critical relaxation thickness of the back barrier layer on the buffer layer.

Example 21: The device of method of any of Examples 1-19 in which the channel layer is thinner than 100 nanometers.

Example 22: The device of method of any of Examples 1-20 in which the channel layer is thinner than 75 nanometers.

Example 23: The device of method of any of Examples 1 -21 in which the channel layer is thinner than 50 nanometers.

Example 24: The device or method of any one of Examples 1-22, where a thickness of the back barrier layer is less than 25 nanometers.

The preceding detailed description and examples are merely illustrative in nature and are not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, or detailed description.

It should be understood that this invention is not limited in its application to the details of construction and the arrangement of components set forth in the preceding description or illustrated in the accompanying drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The preceding discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown, but are to be accorded the widest scope consistent with the principles and features disclosed herein. The preceding detailed description is to be read with reference to the figures, in which like elements in different figures have like reference numerals. The Figures, which are not necessarily to scale, depict selected embodiments and are not intended to limit the scope of embodiments of the invention. Skilled artisans will recognize the examples provided herein have many useful alternatives and fall within the scope of embodiments of the invention.

The connecting lines shown in the various figures contained herein are intended to represent exemplary functional relationships and/or physical couplings between the various elements. It should be noted that many alternative or additional functional relationships or physical connections may be present in one or more embodiments of the subject matter. In addition, certain terminology may also be used herein for the purpose of reference only, and thus are not intended to be limiting, and the terms “first,” “second” and other such numerical terms referring to structures do not imply a sequence or order unless clearly indicated by the context.

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with, electrically or otherwise) another element, and not necessarily mechanically. Thus, although the schematic shown in the figures depict one exemplary arrangement of elements, additional intervening elements, devices, features, or components may be present in one or more embodiments of the depicted subject matter.

What is claimed is:

1. A semiconductor heterostructure transistor, comprising:
a substrate;
a semiconductor buffer layer formed on the substrate;
a semiconductor heterostructure formed above the buffer layer, the heterostructure comprising:
a back barrier layer formed pseudomorphically directly on the buffer layer;
an upper barrier layer disposed above the back barrier layer; and
a channel layer formed between the back barrier layer and the upper barrier layer that contacts the back barrier layer at a first interface and contacts the upper barrier layer at a second interface; and wherein the channel layer is formed a first semiconductor material;
a first current terminal electrically coupled to a first end of the channel layer;
a second current terminal electrically coupled to a second end of the channel layer; and
a gate electrode electrically coupled to the channel layer and disposed above the channel layer between the first current terminal and the second current terminal;
wherein the back barrier layer is formed from a solid solution of the first semiconductor material and a second semiconductor material, the solid solution having a composition that varies with distance from the first interface in a direction perpendicular to the first interface;
wherein the upper barrier layer is formed by a third semiconductor material; and
wherein the channel layer and the upper barrier layer are jointly configured and arranged to cause formation of a two-dimensional charge gas (2DCG) in the channel layer at the second interface.

2. The semiconductor heterostructure transistor of claim 1, wherein both the channel layer and the buffer layer are formed from the first semiconductor material.

3. The semiconductor heterostructure transistor of claim 2, wherein the first semiconductor material is gallium nitride (GaN).

4. The semiconductor heterostructure transistor of claim 1, wherein the channel layer is formed from gallium nitride (GaN), and the back barrier layer is a formed from a solid solution of GaN with indium nitride (InN) having a concentration of indium that is highest near the first interface and decreases away from the first interface and toward the substrate.

5. The transistor of claim 4,
wherein the back barrier layer has a first composition near the first interface that is at least 15% InN and a remainder of the first composition is GaN; and
wherein the back barrier layer has a second composition away from the first interface that is less than 10% InN and a remainder of the second composition is GaN.

6. The semiconductor heterostructure transistor of claim 4, wherein a proportion of InN in the barrier layer decreases linearly with distance from the first interface along the direction perpendicular to the first interface in at least part of the back barrier layer.

7. The semiconductor heterostructure transistor of claim 5, wherein an electronic carrier concentration of the 2DCG at the second interface is at least 100 times larger than an electronic carrier concentration in the back barrier layer at the first interface.

8. The semiconductor heterostructure transistor of claim 5, wherein an electronic carrier concentration of the 2DCG at the second interface is at least 1,000 times larger than an electronic carrier concentration in the back barrier layer at the first interface.

9. The semiconductor heterostructure transistor of claim 1,
wherein the back barrier layer is formed from gallium nitride (GaN); and
wherein the channel layer is formed from gallium nitride (GaN), and the back barrier layer is a solid solution of GaN with aluminum nitride (AlN) having a concentration of aluminum that is lowest at the first interface and increases away from the first interface.

10. The semiconductor heterostructure transistor of claim 9, wherein the proportion of AlN of the back barrier layer increases linearly with distance from the first interface along the direction perpendicular to the first interface in at least part of the back barrier.

11. The semiconductor heterostructure transistor of claim 9, wherein the back barrier layer has a first composition at the first interface that is less than 5% AlN.

12. The semiconductor heterostructure transistor of claim 11, wherein the proportion of AlN of the back barrier layer increases with distance from the first interface along the direction perpendicular to the first interface in at least part of the back barrier.

13. The semiconductor heterostructure transistor of claim 9, wherein the back barrier layer has a second composition away from the first interface that is at least 10% AlN.

14. The semiconductor heterostructure transistor of claim 9, wherein the back barrier layer and the channel layer are jointly configured to prevent formation of a parasitic 2DCG in the back barrier layer.

15. The semiconductor heterostructure transistor of claim 1, wherein a composition gradient within the back-barrier is configured to produce polarization within the back barrier layer that opposes accumulation of charge carriers having a polarity that is the same as a polarity of charge carriers in the 2DCG formed in the channel layer.

16. The semiconductor heterostructure transistor of claim 1, wherein a thickness of the back barrier layer is less than 50 nanometers.

17. A semiconductor heterostructure transistor, comprising:
a substrate;
a buffer layer formed on the substrate formed from a first semiconductor material;
a semiconductor heterostructure formed above the buffer layer, the heterostructure comprising:
a back barrier layer disposed directly on the buffer layer;
a upper barrier layer disposed above the back barrier layer; and
a channel layer formed between the back barrier layer and the upper barrier layer that contacts the back barrier layer at a first interface and contacts the upper barrier layer at a second interface; and wherein the channel layer is formed from the first semiconductor material;
a first current terminal electrically coupled to a first end of the channel layer;
a second current terminal electrically coupled to a second end of the channel layer; and
a gate electrode electrically coupled to the channel layer and disposed above the channel layer between the first current terminal and the second current terminal;
wherein the back barrier layer is formed from a solid solution of the first semiconductor material and a second semiconductor material, the solid solution having a composition that varies with distance from the first interface in a direction perpendicular to the first interface;
wherein the upper barrier layer is formed from a third semiconductor material; and
wherein the channel layer and the upper barrier layer are jointly configured to cause formation of a two-dimensional charge gas (2DCG) in the channel layer at the second interface.

18. The semiconductor heterostructure transistor of claim 17, wherein the back barrier layer is pseudomorphically formed directly on the buffer layer.

19. The semiconductor heterostructure transistor of claim 17, wherein a composition gradient within the back-barrier is configured to produce polarization within the back barrier layer that opposes accumulation of charge carriers having a polarity that is the same as a polarity of charge carriers in the 2DCG formed in the channel layer.

20. The semiconductor heterostructure transistor of claim 18, wherein a thickness of the channel layer is less than 100 nanometers and a thickness of the back barrier layer is less than 50 nanometers.
